(19) United States
(12) Patent Application Publication
(10) Pub. No.: US 2010/0102414 A1
(43) Pub. Date: Apr. 29, 2010

(54) SEMICONDUCTOR DEVICE

(75) Inventors: Miki Yamanaka, Osaka (JP); Yukio Hiraoka, Hyogo (JP); Osamu Ishikawa, Kyoto (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/650,611

(22) Filed: Dec. 31, 2009

Related U.S. Application Data
(62) Division of application No. 11/465,151, filed on Aug. 17, 2006.

(30) Foreign Application Priority Data
Aug. 29, 2005 (JP) 2005-248269

(51) Int. Cl. H01L 29/06

(52) U.S. Cl. 257/501; 257/E29.02

(57) ABSTRACT

The present invention aims at providing a semiconductor device that can prevent quality degradation of a signal caused by noise, reduce a malfunction of a circuit caused by latch-up, and secure favorable isolation, and the semiconductor device includes: a first layer with a resistivity higher than 10·cm and lower than 1 k·cm which is formed in a semiconductor substrate; a second layer formed on a surface of the semiconductor substrate so as to be located above the first layer; two semiconductor devices formed in the second layer or on the second layer; and a trench-type insulating region which is located between the two semiconductor devices, is formed in the semiconductor substrate so as to reach the first layer from the surface of the semiconductor substrate, and electrically isolates the two semiconductor devices.

### CROSS-REFERENCE RELATED TO APPLICATION

This application is a divisional of pending U.S. application Ser. No. 11/465,151 filed on Aug. 17, 2006, which claims priority to Japanese Application No. 2005-248269, filed Aug. 29, 2005, the disclosure of which is expressly incorporated herein by reference in its entirety.

### BACKGROUND OF THE INVENTION

(1) Field of the Invention

The present invention relates to a semiconductor device from a baseband to a radio frequency (RF) band, in which a semiconductor circuit and a semiconductor element provided in an analog circuit, a digital circuit or an analog-digital mixed circuit are formed, and particularly to a semiconductor device which prevents signal interference between elements or between blocks.

(2) Description of the Related Art

In recent years, there is a growing demand for miniaturizing and reducing the cost of modules used in a cellular phone, a mobile information terminal and the like. In response to such a demand, area reductions in chip layout, and use of single-chips in the RF or baseband and digital-analog mixed chips have been promoted. However, signal interference increases between elements, blocks, or chips in a semiconductor device with the aforementioned structure, and the interference hampers signal processing. Thus, it is necessary to take favorable isolation measures in the semiconductor device.

As conventional technology regarding element isolation reported for a purpose of securing such isolation, there exists a semiconductor device described in MIKE GOLIO, “The RF AND MICROWAVE HANDBOOK” CRC Press, 2000 7-51, FIG. 7.43 (hereinafter referred to as Reference 1). In this semiconductor device, as shown in FIG. 1, a bipolar transistor including a base 1001, a collector 1003 and an emitter 1002 is formed in an n-type semiconductor layer which has a resistivity lower than that of a p-type silicon substrate 1000 and is formed on the p-type silicon substrate 1000. In addition, trenches 1004 are formed in a depth direction vertical to a surface of the semiconductor layer and within the semiconductor layer, so as to sandwich the bipolar transistor, and insulating material is embedded in the trenches 1004. In addition, the trenches 1004 are formed so as to reach the silicon substrate 1000.

In the semiconductor device with such a structure, the trenches 1004 can prevent signal interference to a horizontal direction parallel to the surface of the semiconductor layer. Since a capacitor with a PN junction depletion layer is formed below the element region where the bipolar transistor is formed, in other words, below the element region sandwiched by the two trenches 1004, the signal interference to the depth direction can be prevented. As a result, isolation can be secured between the elements.

In addition, as other conventional technology regarding element isolation, there exists a semiconductor device described in Daisuke Kosaka, Makoto Nagata (Kobe University), Kousei Hiraoka, Ikuo Imanishi, Masakatsu Maeda (Matsushita Electric Industrial Co., Ltd.), Yoshitaka Murasaka, Atushi Iwata (A-R-Tec Corporation), Isolation Strategy against Substrate Coupling in CMOS Mixed-Signal/RF Circuits, the IEICE Electronics Society Technical Committee on Integrated Circuits and Devices (ICD), general presentation (experiment) (hereinafter referred to as Reference 2). In this semiconductor device, as shown in FIG. 2, a well region 1102 in which a semiconductor element is formed is formed in a silicon substrate 1101 with a resistivity equal to 1 kΩcm or more.

As in the semiconductor device having such a structure, a capacitor with a PN junction depletion layer is formed in the periphery of the semiconductor element, the signal interference can be prevented between two semiconductor elements formed on the same substrate. In addition, as the resistivity of the substrate in the periphery of the semiconductor device is high, the signal that propagates through the substrate is attenuated. As a result, isolation can be secured in the semiconductor device.

In addition, as other conventional technology regarding element isolation, there exists a semiconductor device described in Japanese Laid-Open Patent Application No. 2004-253633 (hereinafter referred to as Patent Document 1). As shown in FIG. 3, in this semiconductor device, a silicon substrate 1200 includes: trenches 1203 in which insulating material is respectively embedded inside; a high resistivity layer 1201 with a resistivity equal to 1 kΩcm or more; a low resistivity layer 1202 with a resistivity lower than that of the high resistivity layer 1201; and a semiconductor element 1204 sandwiched by the trenches 1203 and formed in the low resistivity layer 1202.

In the semiconductor device having such a structure, as a trench is formed between the semiconductor elements, signal interference to the horizontal direction parallel to a surface of the silicon substrate can be prevented. In addition, as the resistivity of the substrate below the semiconductor element is high, a signal that propagates through a part below the trenches, in other words, a signal that propagates through a horizontal direction in a part deeper than a predetermined depth is attenuated. As a result, isolation can be secured in the semiconductor device.

### SUMMARY OF THE INVENTION

Normally, in an analog circuit or a digital circuit, a signal generated in an element region in which a semiconductor device is formed is propagated to other device regions by a parasitic capacitor or a resistor which is present in a substrate, on a surface of the substrate, or in the periphery of the surface of the substrate. This signal becomes noise for circuits, chips, or devices other than the devices which generate the signal, and degrades quality of signals present in other parts. In particular, the more the area reductions in module layout, and use of digital-analog mixed chips and single-chips in the RF or baseband have been promoted, the more remarkable this problem becomes.

However, the semiconductor device described in Reference 1 prevents signals from propagating through below the semiconductor element, using a capacitor with a PN junction depletion layer. Thus, for example, in the case where an RF signal with frequency equal to 800 MHz or more is used, it is not possible to secure sufficiently high impedance. As a result, the signal easily propagates through the horizontal direction via a substrate region below trenches, and then the propagated signal again propagates through the upward direction, which causes an occurrence of a crosstalk. Therefore, this semiconductor device can not secure favorable isolation.

In addition, likewise the semiconductor device described in Reference 2, the signal propagation through other semiconductor elements is prevented using a capacitor including a PN junction depletion layer. Thus, in the case where an RF signal with frequency equal to 800 MHz or more is used, it is not possible to secure sufficiently high impedance. As a result, a crosstalk occurs, and even with this semiconductor device, favorable isolation can not be realized.

Furthermore, in the semiconductor devices described in Reference 2 and Patent Document 1, a crosstalk is prevented by forming a region with a high resistivity in the periphery of the semiconductor element in the substrate and attenuating a signal which leaks from the semiconductor element and propagates through the substrate. However, the more the resistivity of the substrate increases, the more thermal noise generated in the substrate increases. Then, as the semiconductor element formed on a surface of the semiconductor substrate picks up this thermal noise via a parasitic capacitor of a substrate and the like, quality of signals in the semiconductor element is degraded. In addition, as crystal defect easily occurs when the substrate resistivity is high, latch-up caused by leakage current in a PN junction easily occurs, and the circuit operation becomes unstable.

Furthermore, in the semiconductor device described in Patent Document 1, the signal interference is prevented by forming a trench between a plurality of semiconductor elements in the semiconductor substrate. However, when further favorable isolation is required, this layout is not sufficient.

Thus, in view of the aforementioned problems, the first object of the present invention is to provide a semiconductor device that can secure favorable isolation while preventing degradation of signal quality caused by noise and reducing a malfunction in the circuit caused by latch-up.

In addition, the second object of the present invention is to provide a semiconductor device that can improve isolation.

In order to achieve above objects, the semiconductor device according to the present invention is a semiconductor device including a first layer which is formed in a semiconductor substrate and has a resistivity higher than 10 Ωcm and lower than 1 kΩcm; a second layer formed on a surface of the semiconductor substrate so as to be located above the first layer; two semiconductor elements or two semiconductor circuits which are formed in the second layer or on the second layer; and at least one isolation region that electrically isolates the two semiconductor elements or the semiconductor circuits, the isolation region being located between the two semiconductor elements or between the two semiconductor circuits and formed in the semiconductor substrate so as to reach the first layer from the surface of the semiconductor substrate. Here, the semiconductor element may be a digital circuit element.

With this, the diffusion of noise generated in a semiconductor element or a semiconductor circuit is prevented by an isolation region and the first layer with a high resistivity. Thus, it is possible to secure favorable isolation for an RF signal with frequency equal to 800 MHz or more. In addition, the resistivity of the first layer is defined as a resistivity higher than 10 Ωcm and lower than 1 kΩcm. Thus, the generation of thermal noise and latch-up can be prevented. As a result, a malfunction of the circuit can be reduced, and degradation of the quality of the signal can be prevented. Thus, it is possible to secure favorable isolation while preventing the degradation of the quality of the signal and reducing the malfunction of the circuit.

In addition, two isolation regions may be formed between the two semiconductor elements or the two semiconductor circuits.

With this, as the two isolation regions can prevent signal interference between the semiconductor elements and semiconductor circuits by the two isolation regions, it is possible to improve the isolation in the semiconductor device.

In addition, the semiconductor device may include a high resistivity region which is formed between the two isolation regions in the second layer and has a resistivity higher than a resistivity of the second layer.

With this, as the high resistivity region can prevent signal interference between the semiconductor elements and semiconductor circuits, it is possible to improve the isolation in the semiconductor device.

In addition, the semiconductor device may include an embedded layer which is formed in the first layer so as to contact the second layer and has a resistivity lower than the resistivity of the first layer.

With this, as noise can be led to the outside part via the low resistivity region, it is possible to improve the isolation in the semiconductor device.

In addition, the first isolation region which is one of the two isolation regions is formed so as to surround one of the two semiconductor elements or one of the two semiconductor circuits, and the second isolation region which is the other of the two isolation regions among the two isolation regions is formed so as to surround the first isolation region.

With this, as a distance between the semiconductor elements or semiconductor circuits which are adjacent to each other increases and an attenuation effect of a signal in the first layer with a high resistivity can be enhanced, it is possible to improve the isolation in the semiconductor device.

In addition, the semiconductor device may include an embedded layer having a conductivity type which is different from a conductivity type of the first layer and formed in the first layer so as to contact the second layer.

With this, as a PN junction depletion layer is formed at the part below the semiconductor element or semiconductor circuit, it is possible to improve the isolation in the semiconductor device.

In addition, the semiconductor device may include an embedded layer which is formed in the first layer so as to contact the second layer and has resistivity lower than that of the first layer.

With this, as noise can be led to the outside part via the region with a low resistivity, it is possible to improve the isolation in the semiconductor device.

Thus, according to the semiconductor device in the present invention, it is possible to secure favorable isolation while preventing degradation of the quality of signals caused by noise and reducing a malfunction of a circuit. In addition, it is possible to reduce the malfunction of a circuit caused by latch-up while preventing increase in a chip area. In other words, the semiconductor device can be miniaturized while a stable circuit operation can be secured. Moreover, these effects are not limited by the frequency band, device for use, or the system of the semiconductor device.

### FURTHER INFORMATION ABOUT TECHNICAL BACKGROUND TO THIS APPLICATION

The disclosure of Japanese Patent Application No. 2005-248269 filed on Aug. 29, 2005 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a cross-sectional diagram showing a structure of a conventional semiconductor device described in Reference 1.

FIG. 2 is an oblique perspective diagram showing a structure of a conventional semiconductor device described in Reference 2.

FIG. 3 is a cross-sectional diagram showing a structure of a conventional semiconductor device described in Patent Document 1.

FIG. 4 is a cross-sectional diagram of the semiconductor device according to the first embodiment of the present invention.

FIG. 5 is a graph showing resistivity dependency on isolation for RF signals with frequency of 100 MHz.

FIG. 6 is a graph showing resistivity dependency on isolation for RF signals with frequency of 1 GHz.

FIG. 7 is a graph showing resistivity dependency on thermal noise.

FIG. 8 is a cross-sectional diagram showing a structure of the semiconductor device according to the second embodiment of the present invention.

FIG. 9 (a) is a top surface view of the semiconductor device according to the third embodiment.

FIG. 9 (b) is a cross sectional view (cross sectional view in A-A′ line of FIG. 9 (a)) of the semiconductor device according to the same embodiment as FIG. 9(a).

FIG. 10 (a) is a top surface view of the semiconductor device according to the fourth embodiment.

FIG. 10 (b) is a cross sectional view (cross sectional view in A-A′ line of FIG. 10 (a)) of the semiconductor device according to the same embodiment as FIG. 10 (a).

FIG. 11 (a) is a top surface view of the semiconductor device according to the fifth embodiment.

FIG. 11 (b) is a cross sectional view (cross sectional view in A-A′ line of FIG. 11 (a)) of the semiconductor device according to the same embodiment as FIG. 11 (a).

FIG. 12 is a cross-sectional diagram showing a structure of the first test pattern used in the experiment.

FIG. 13 is a cross-sectional diagram showing a structure of the second test pattern used in the experiment.

FIG. 14 is a cross-sectional diagram showing a structure of the third test pattern used in the experiment.

FIG. 15 is a graph showing frequency dependency on isolation in the first, second, and third test patterns in the case where the resistivity of the first layer is 10 Ωcm.

FIG. 16 is a graph showing frequency dependency on isolation in the first, second, and third test patterns in the case where the resistivity of the first layer is 100 Ωcm.

FIG. 17 is a graph showing frequency dependency on isolation in the first, second, and third test patterns in the case where the resistivity of the first layer is 1 kΩcm.

FIG. 18 is a graph showing frequency dependency on isolation in the first, second, and third test patterns in the case where the resistivity of the first layer is 2 kΩcm.

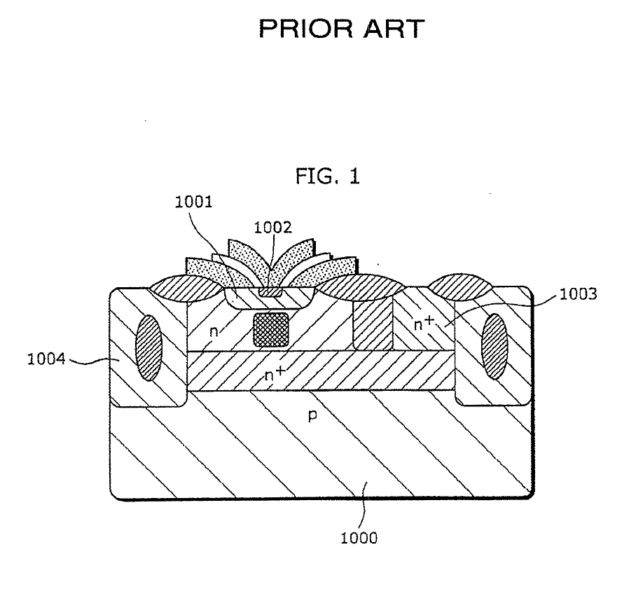

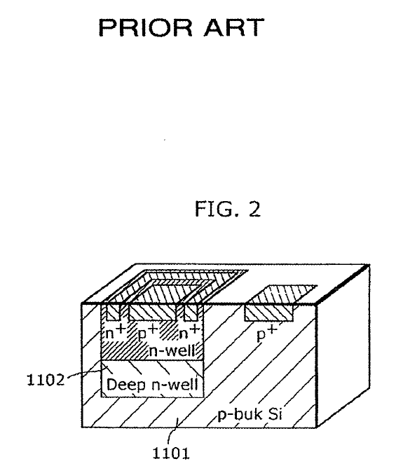

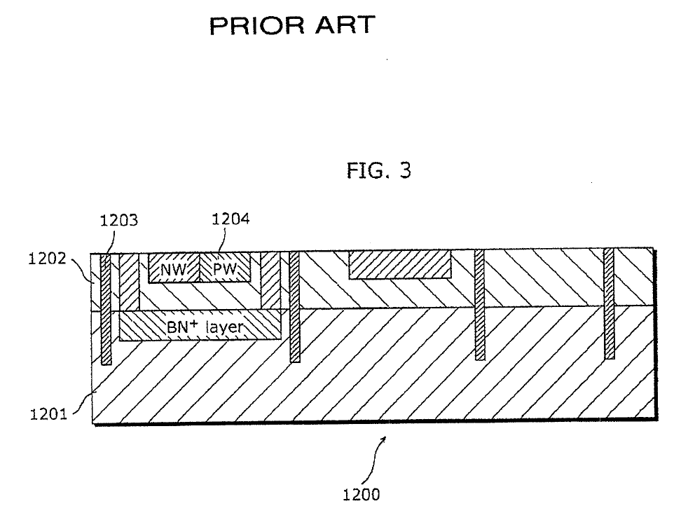

### DESCRIPTION OF THE PREFERRED EMBODIMENTS

The semiconductor device in the embodiments of the present invention is described hereinafter with reference to the diagrams.

### First Embodiment

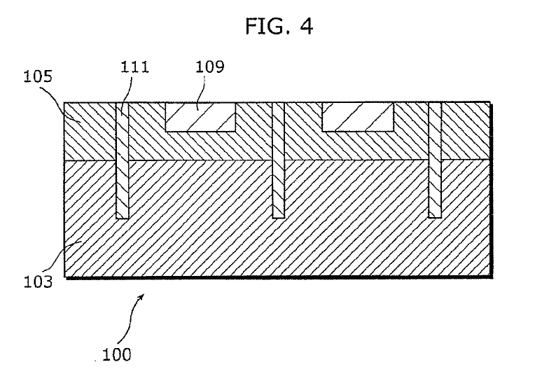

FIG. 4 is a cross sectional view showing a structure of the semiconductor device according to the first embodiment.

In this semiconductor device, a first layer 103, a second layer 105, and trench-type insulating regions 111 are formed in a semiconductor substrate 100.

The first layer 103 is a high resistivity substrate of a first conductivity type having a resistivity higher than 10 Ωcm and lower than 1 kΩcm, and is formed in the semiconductor substrate 100.

The second layer 105 is a low resistivity substrate of a second conductivity type having a resistivity lower than that of the first layer 103, for example, having low resistivity of 10 Ωcm, and is formed on a surface side in the semiconductor substrate 100 so as to be located above the first layer 103. In a predetermined part of the second layer 105, a plurality of semiconductor elements or semiconductor circuits (hereinafter simply referred to as semiconductor elements) 109 are formed. Moreover, the semiconductor element 109 is, for example, an integrated circuit such as an analog circuit, a digital circuit or an RF circuit, an active element such as a bipolar transistor or a MOS transistor, or a passive element such as a resistor, an inductor or a capacitor.

In this case, the first layer 103 and the second layer 105 may be formed by epitaxial growth, or by an ion-implantation in the substrate. The trench-type insulating regions 111 are formed so as to respectively surround the semiconductor element 109, and electrically isolates two of the semiconductor elements 109.

The trench-type insulating regions 111 vertically runs from the surface of the semiconductor substrate 100 to the depth direction across the second layer 105 so as to horizontally divide the second layer 105. The trench-type insulating regions 111 are made up of trenches, having, for example, the depth of 3 micron (μm), and the insulating material is embedded inside.

In the semiconductor device having the aforementioned structure, by operating the semiconductor element 109, a signal (noise for other elements and circuits) or noise caused by the signal is generated. However, unless the measures are taken, the signal or the noise caused by the signal is diffused to a horizontal direction parallel to the surface of the semiconductor substrate 100 and the depth direction vertical to the semiconductor substrate 100.

However, in the aforementioned semiconductor device, as the trench-type insulating regions 111 are formed so as to respectively surround the semiconductor element 109, the propagation of the is signal or the noise caused by the signal to the horizontal direction is prevented. In addition, the signal or the noise caused by the signal that can not be propagated to the horizontal direction by the trench-type insulating regions 111 has only to pass a path to the depth direction. However, as the trench-type insulating regions 111 are formed so as to reach the first layer 103 from the surface of the substrate, this indicates that the first layer 103 with a high resistivity (resistivity higher than 10 Ωcm and lower than 1 k Ωcm) is present in a signal path of the depth direction, and that the signal or the noise caused by the signal which propagates through the depth direction is attenuated by the first layer 103. Therefore, with this structure, favorable isolation can be secured in the semiconductor device.

On the other hand, one of the causes of a malfunction in a circuit is latch-up. This occurs because leakage current in a PN junction flows through a substrate resistor, and a voltage of the substrate increases by ΔV (=substrate resistor×leakage current).

In this case, the more the resistivity of a silicon substrate increases, the more it includes crystal defect. Therefore, the high resistivity in a substrate causes the increase of the leakage current. Thus, in the case where the substrate is made into a high resistivity in order to secure favorable isolation, both the resistance value of the substrate resistor and the current value of leakage current which determine the [symbol] increase. As a result, the latch-up easily occurs, and a malfunction in a circuit easily occurs.

In this case, in the aforementioned semiconductor device, as the layout, the longer a distance between a part where a substrate potential is fixed and the semiconductor element becomes, the longer the path where the leakage current flows. As a result, the resistance value of the substrate resistor increases. In addition, in the case where the area of such a part is small, the resistance value of parasitic resistor increases. Therefore, as a method of preventing an occurrence of latch-up, it is conceivable to form a part of the substrate which has a sufficiently large area and in which the substrate potential is fixed in an adjacent to the semiconductor element. However, this method, consequently, leads to the increase of a chip area.

In addition, a resistor causes thermal noise, and noise voltage V_{T} is determined by the equation of V_{T}=(4 kTBR)^{1/2}. Here, k indicates a Boltzmann constant (J/K), B indicates noise bandwidth (Hz), T indicates absolute temperature (K), and R indicates resistance value (Ω). Then, the thermal noise caused by a substrate resistor is added to the semiconductor element through a parasitic capacitor of the substrate. Therefore, in the case where the substrate is made into a high resistivity in order to secure favorable isolation, the higher the substrate resistivity becomes, the more thermal noise increases as shown in the aforementioned equation because much noise is added to the semiconductor element. As a result, the quality of the signal becomes further degraded.

Thus, in order to reduce the malfunction in the circuit and prevent degradation of the signal quality, it is necessary not to increase resistance value of the substrate resistor more than requires.

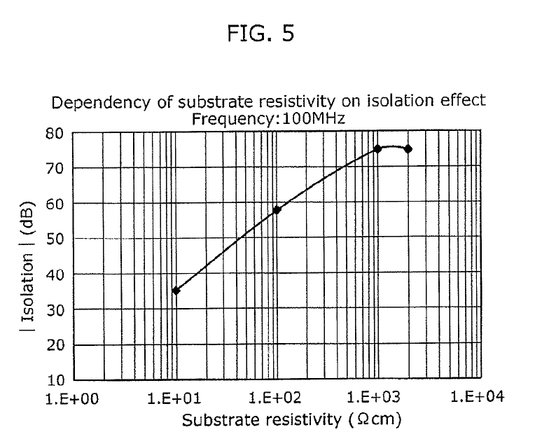

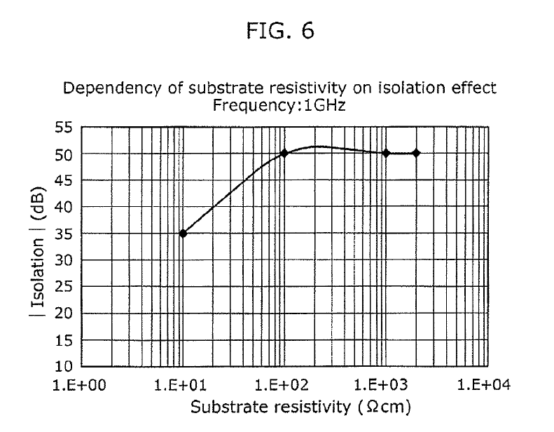

In the aforementioned semiconductor device, as shown in an experiment result graph of FIG. 5 indicating dependency on a resistivity (resistivity of the first layer 103) of isolation for RF signals with frequency of 100 MHz, isolation for the RF signals with frequency of 100 MHz increases in proportion to the substrate resistivity. However, the isolation becomes saturated with a resistivity equal to 1 kΩcm or more. In addition, as shown in an experiment result graph of FIG. 6 indicating dependency on a resistivity (resistivity of the first layer 103) of isolation for RF signals with frequency of 1 GHz, the resistivity with which isolation is becomes saturated is lowered according to the increase in frequency of the RF signal. As a result, there is no difference in isolation effect between a substrate with a resistivity of 100 Ωcm and a substrate with a resistivity of 1 k Ωcm. In other words, in the aforementioned semiconductor device, isolation is not improved for the RF signals with frequency equal to 100 MHz or more even by increasing the resistivity over a predetermined resistance value which is a resistivity less than 1 kΩcm.

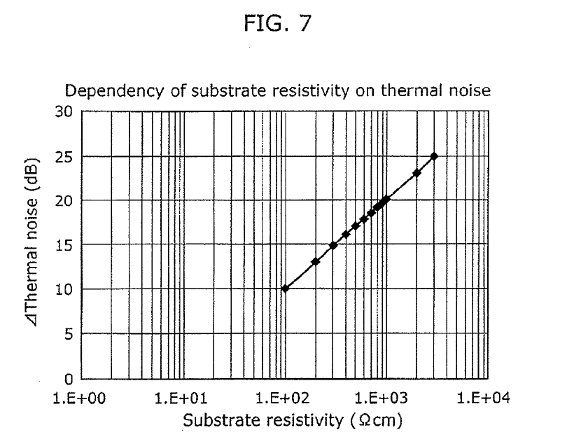

In addition, as shown in an experiment result graph of FIG. 7 indicating dependency on a resistivity (resistivity of the first layer 103) of thermal noise, the thermal noise voltage caused by the substrate resistor increases in proportion to the substrate resistivity. Therefore, in the case where the substrate resistivity is designated as equal to 1 kΩcm or more, isolation becomes saturated, and a malfunction that only noise increases occurs. In addition, as described earlier, factors responsible for malfunctions in the circuit may increase. Moreover, in FIG. 7, the thermal noise indicates an amount of degraded thermal noise from the standard, on a basis of the thermal noise in the case where the resistivity of the first layer 103 is 10 Ωcm.

In addition, as shown in the experiment result graphs of FIG. 5 and FIG. 6, in the case where the resistivity of the first layer 103 is close to 10 Ωcm which is a resistivity of a general semiconductor substrate, the higher the resistivity becomes, the more the isolation effect is improved.

In consideration of the aforementioned results, by designating the lower limit of the resistivity of the first layer 103 as 10 Ωcm which is a resistivity of a general semiconductor substrate and the upper limit as 1 kΩcm, it is found that favorable isolation can be secured in the semiconductor device, the malfunction in the circuit can be reduced, and quality degradation of a signal can be prevented for an RF signal with frequency of equal to 100 MHz or more.

In this case, even for an RF signal with frequency higher than 1 GHz, as isolation becomes saturated with the resistivity of about 100 Ωcm, the lower limit of the resistivity of the first layer 103 may be designated as 100 Ωcm. With this, it is possible to realize more favorable isolation.

As described, according to the semiconductor device of the present embodiment, it is possible to prevent quality degradation of a signal caused by noise and to reduce a malfunction caused by latch-up in the circuit as well as to secure favorable isolation. In addition, it is possible to prevent increase of a chip area and to reduce a malfunction caused by latch-up in the circuit.

Although the semiconductor element 109 is formed in the second layer 105 according to the semiconductor device of the present embodiment, it may be formed on the second layer 105.

### Second Embodiment

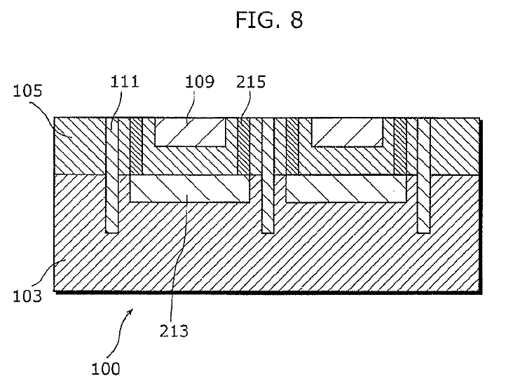

FIG. 8 is a cross section view showing a structure of the semiconductor device according to the second embodiment.

This semiconductor device differs from the semiconductor device in the first embodiment in having first embedded layers 213 formed in the first layer 103 and second embedded layers 215 formed in the second layer 105.

The first embedded layer 213 is a second conductivity-type low resistivity layer having a resistivity lower than that of the first layer 103 so as to be formed in contact with the second layer 105.

The second embedded layer 215 is a second conductivity-type low resistivity layer having a resistivity lower than that of the first layer 103 and is formed so as to surround the semiconductor element 109 and be located between the trench-type insulating region 111 and the semiconductor element 109. The second embedded layers 215 vertically run from the surface of the semiconductor substrate 100 to the depth direction across the second layer 105 so as to horizontally divide the second layer 105, and have the depth enough to reach the first embedded layer 213.

In this case, the first embedded layers 213 and second embedded layers 215 are formed by implanting, in the first layer 103 and second layer 105, for example, p-type impurity ions, such as boron (B) ions, aluminum (Al) ions, a gallium (Ga) ions, indium (In) ions, or the like.

As described, according to the semiconductor device of the present embodiment, the semiconductor element 109 is surrounded by the first embedded layer 213 and the second embedded layer 215 which have a low resistivity. Thus, by connecting the first embedded layer 213 and the second embedded layer 215 to an outer ground (not illustrated), noise can be led to the outside part. Thus, it is possible to improve isolation in the semiconductor device.

In addition, as a PN junction depletion layer is formed between the first embedded layer 213 below the semiconductor element 109 and the first layer 103, it is possible to improve isolation in the semiconductor device of the present embodiment.

### Third Embodiment

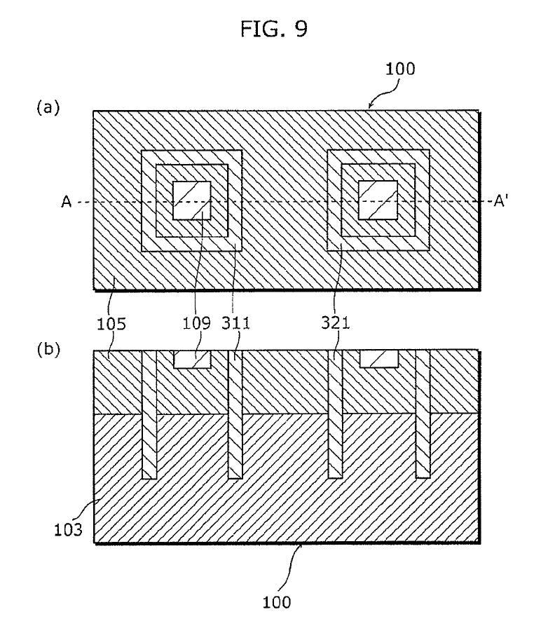

FIG. 9 (a) is a top surface view of the semiconductor device according to the third embodiment, and FIG. 9 (b) is a cross sectional view of the same semiconductor device (cross sectional view in A-A′ line of FIG. 9 (a)).

This semiconductor device differs from the semiconductor device in the first embodiment in having a plurality of trench-type insulating regions between two semiconductor elements 109, in other words, having a first trench-type insulating region 311 and a second trench-type insulating region 321.

The first trench-type insulating region 311 and the second trench-type insulating region 321 are formed so as to surround each of the semiconductor elements 109, and electrically isolate the surrounded semiconductor element 109 from the other semiconductor elements 109. The first trench-type insulating region 311 and the second trench-type insulating region 321 vertically run from the surface of the semiconductor substrate 100 to the depth direction across the second layer 105 so as to horizontally divide the second layer 105. The first trench-type insulating region 311 and the second trench-type insulating region 321 are made up of trenches in which the insulating material is embedded inside, and have the depth enough to reach the first layer 103, for example, the depth of 3 micron (μm).

As described, in the aforementioned semiconductor device of the present embodiment, each of the plurality of semiconductor elements 109 is surrounded by each of the trench-type insulating regions. Therefore, as it is certain that signal interference occurring between elements can be prevented, it becomes possible to improve isolation (between the elements) in the semiconductor device.

### Fourth Embodiment

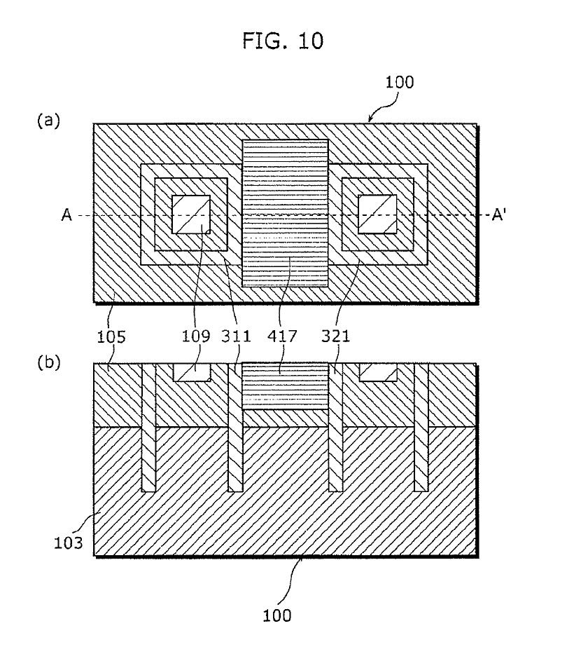

FIG. 10 (a) is a top surface view of the semiconductor device according to the fourth embodiment, and FIG. 10 (b) is a cross sectional view of the same semiconductor device (cross sectional view in A-A′ line of FIG. 10 (a)).

This semiconductor device differs from the semiconductor device in the third embodiment in having a high resistivity region 417 between two trench-type insulating regions which surround each of the semiconductor elements 109.

The high resistivity region 417 is a high resistivity layer (for example, an oxidation layer) with a resistivity higher than that of the first layer 103 and the second layer 105, which is formed in the second layer 105 so as to be located between the first trench-type insulating region 311 and the second trench-type insulating region 321. In this case, the high resistivity region 417 may vertically run from the surface of the semiconductor substrate 100 to the depth direction across the second layer 105 so as to horizontally divide the second layer 105, and may have the depth enough to reach the first layer 103.

As described, in the aforementioned semiconductor device of the present embodiment, the high resistivity region 417 with a resistivity higher than that of the first layer 103 and the second layer 105 is formed in the second layer 105 which is located between the first trench-type insulating layer 311 and the second trench-type insulating layer 321, each of which surrounds the semiconductor element 109. As it is certain that signal interference occurring between elements can be prevented, it becomes possible to improve isolation between the elements.

Moreover, in the aforementioned semiconductor device of the present embodiment, the high resistivity region 417 is formed in the second layer 105 which is located between two of the trench-type insulating regions. However, for example, by performing high-concentration doping of second conductivity-type impurities on the second layer 105 or forming a metal layer on the second layer 105, a low resistivity region which is fixed at a potential with a resistivity lower than that of the second layer 105 may be formed in the second layer 105 between the two trench-type insulating regions instead of the high resistivity region 417. In addition, the aforementioned high resistivity region and low resistivity region may be formed at the same time. With this, noise can be led to the outside part. Thus, it is possible to improve isolation likewise the case where a high resistivity region is formed.

### Fifth Embodiment

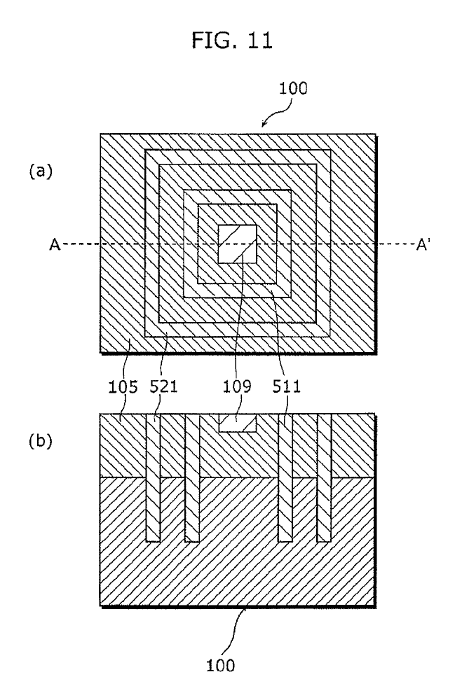

FIG. 11 (a) is a top surface view of the semiconductor device according to the fifth embodiment, and FIG. 11 (b) is a cross sectional view of the same semiconductor device (cross sectional view in A-A′ line of FIG. 11 (a)).

This semiconductor device differs from the semiconductor device in the first embodiment in having a plurality of trench-type insulating regions which doubly surround the semiconductor element 109, in other words, having a third trench-type insulating region 511 and a fourth trench-type insulating region 521.

The third trench-type insulating region 511 is formed so as to surround the semiconductor element 109, and electrically isolates the surrounded semiconductor element 109 from the other semiconductor elements 109. The third trench-type insulating region 511 vertically runs from the surface of the semiconductor substrate 100 to the depth direction across the second layer 105 so as to horizontally divide the second layer 105, is made up of a trench in which the insulating material is embedded inside, and has the depth enough to reach the first layer 103, for example, the depth of 3 micron (μm).

The fourth trench-type insulating region 521 is formed so as to surround the third trench-type insulating region 511, electrically isolates the semiconductor element 109 surrounded by the third trench-type insulating region 511 from the other semiconductor elements 109. The fourth trench-type insulating region 521 vertically runs from the surface of the semiconductor substrate 100 to the depth direction across the second layer 105 so as to horizontally divide the second layer 105, is made up of a trench in which the insulating material is embedded Inside, and has the depth enough to reach the first layer 103, for example, the depth of 3 micron (μm).

As described, in the aforementioned semiconductor device of the present embodiment, the two or more trench-type insulating regions which surround the semiconductor element 109 are formed for some of the semiconductor elements. As a distance between adjacent semiconductor elements increases and an attenuation effect of the signal in the first layer with a high resistivity can be enhanced, it becomes possible to improve isolation between is elements.

### Experiment Example

The experiment examples of the semiconductor device according to the first, the third and the fourth embodiments are described hereinafter.

Three test patterns are prepared: a first test pattern corresponding to the semiconductor device in the first embodiment; a second test pattern corresponding to the semiconductor device in the third embodiment; and a third test pattern corresponding to the semiconductor device in the fourth embodiment.

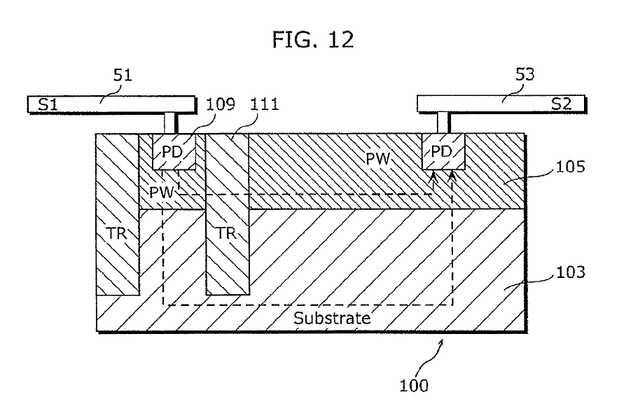

The First test pattern has a cross sectional structure as shown in FIG. 12. In other words, the first test pattern has a cross sectional structure in which only the semiconductor element (photodiode) 109 connected to an S1 port 51 among the two semiconductor elements (photodiode) 109 which are respectively connected to the S1 port 51 and a S2 port 53, is surrounded by the trench-type insulating regions 111.

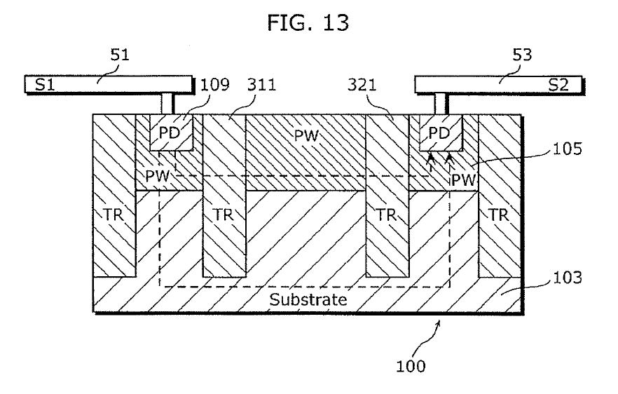

The second test pattern has a cross sectional structure as shown in FIG. 13. In other words, the second test pattern has a cross sectional structure in which both of the semiconductor elements (photodiode) 109 each connected to the S1 port 51 and the S2 port 53 are surrounded respectively by the first trench-type insulating layer 311 and the second trench-type insulating layer 321.

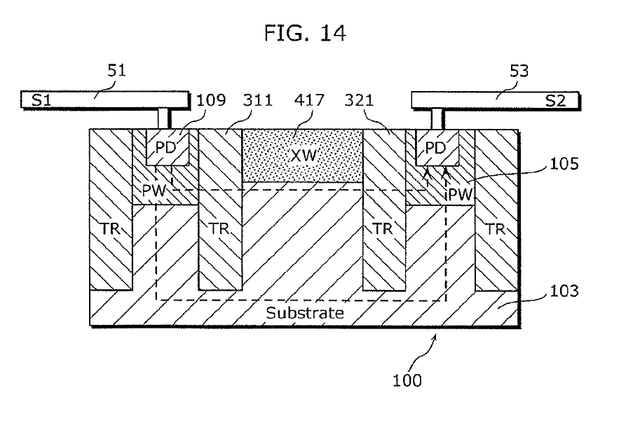

The third test pattern has a cross sectional structure as shown in FIG. 14. In other words, the third test pattern has a cross sectional structure in which both of the semiconductor elements (photodiode) 109 each connected to the S1 port 51 and the S2 port 53 are surrounded respectively by the first trench-type insulating layer 311 and the second trench-type insulating layer 321, and the high resistivity region 417 is formed between the first trench-type insulating layer 311 and the second trench-type insulating layer is 321.

In this case, the resistivity of the first layer 103 is designated as 100 Ωcm, 1 kΩcm or 2 k Ωcm in order to conduct a comparison with a high resistivity substrate having a standard nominal resistivity of 10 Ωcm, using a wafer which has a thickness of 300 um prototyped in a CMOS mixed signal process and is a standard wafer of 0.25 μm. Then, the resistivity of the second layer 105 is designated as 1 Ωcm, and the depth of the trench-type insulating region 111, the first trench-type insulating region 311 and the second trench-type insulating region 321 is designated as 3 μm.

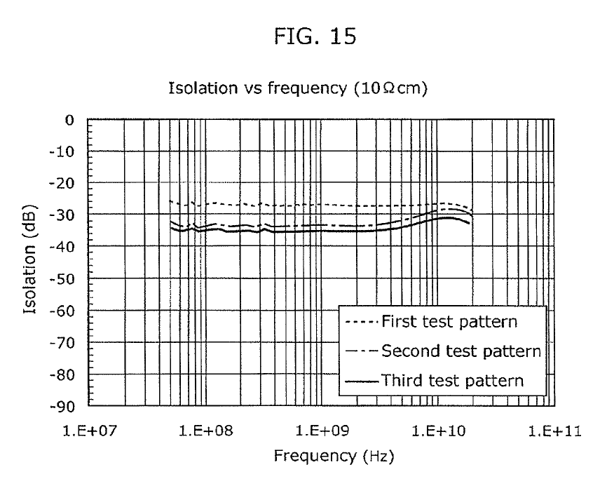

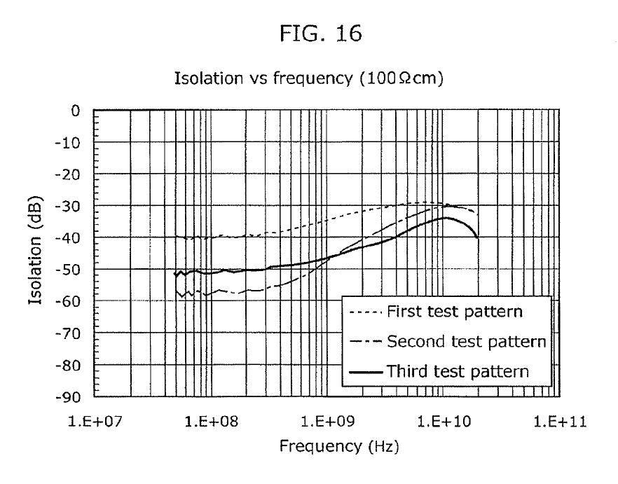

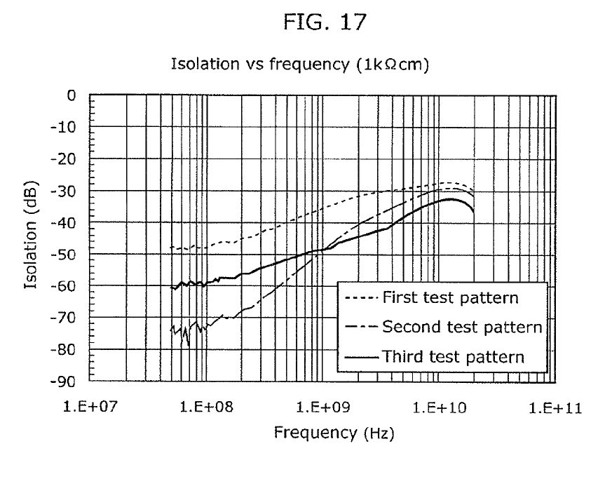

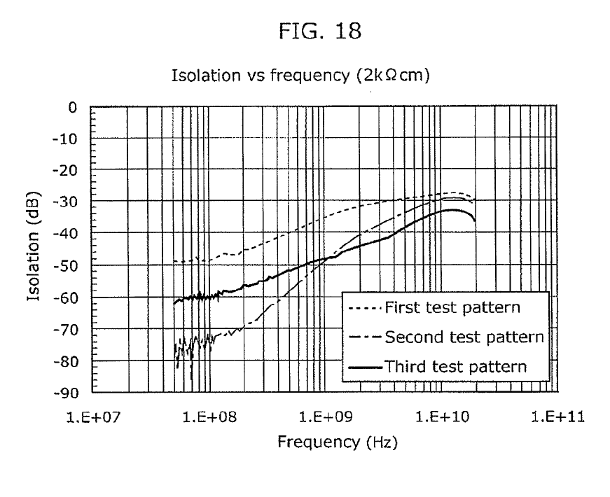

FIGS. 15 to 18 are graphs showing the result of the experiments regarding the frequency dependency on isolation, which are performed according to each of the test patterns. FIG. 15 indicates the frequency dependency on isolation between the S1 port 51 and the S2 port 53 in each test pattern in the case where the resistivity of the first layer 103 is 10 Ωcm. In addition, FIG. 16 indicates the frequency dependency on isolation between the S1 port 51 and the S2 port 53 in each test pattern in the case where the resistivity of the first layer 103 is 100 Ωcm. In addition, FIG. 17 indicates the frequency dependency on isolation between the S1 port 51 and the S2 port 53 in each test pattern in the case where the resistivity of the first layer 103 is 1 kΩcm. In addition, FIG. 18 indicates the frequency dependency on isolation between the S1 port 51 and the S2 port 53 in each test pattern in the case where the resistivity of the first layer 103 is 2 kΩcm.

As isolation in the second test pattern and the third test pattern is improved by 5 dB to 20 dB or more, compared to isolation in the first test pattern according to FIGS. 15 to 18, it is found that a higher isolation effect can be obtained by forming a plurality of trench-type insulating regions between a plurality of semiconductor elements. In addition, as it is indicated that isolation in the third test pattern is improved by approximately 5 dB for an RF signal with frequency of equal to 1 GHz or more, compared to isolation in the second test pattern, it is found that a higher Isolation effect, in particular, for an RF signal with frequency of equal to 1 GHz or more, can be obtained by forming a high resistivity region between trench-type insulating regions.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The present invention can be applied to a semiconductor device, in particular, to a semiconductor device and the like from a baseband to an RF band in which a semiconductor circuit and a semiconductor device provided in an analog circuit, a digital circuit an analog-digital mixed circuit are formed.

What is claimed is:

1. A semiconductor device, comprising:
a first layer formed in a semiconductor substrate and having a resistivity greater than 100 Ωcm and less than 1 kΩcm;
a second layer formed on a surface of the semiconductor substrate so as to be located above the first layer;
two semiconductor elements or two semiconductor circuits formed either in said second layer or on said second layer; and
at least one isolation region that either electrically isolates said two semiconductor elements or that electrically isolates said two semiconductor circuits, said at least one isolation region being located either between said two semiconductor elements or between said two semiconductor circuits and formed in the semiconductor substrate so as to reach said first layer from the surface of the semiconductor substrate, said at least one isolation region comprising two isolation regions formed either between said two semiconductor elements or between said two semiconductor circuits; and
a high resistivity region is formed between said two isolation regions in said second layer and has a resistivity higher than a resistivity of said second layer.

2. The semiconductor device according to claim 1, further comprising:
a low resistivity region formed between said two isolation regions in said second layer having a fixed potential value and having a resistivity lower than the resistivity of said second layer.

3. The semiconductor device according to claim 2,
wherein said semiconductor element is a digital circuit element.

4. The semiconductor device according to claim 1,
wherein said semiconductor element is a digital circuit element.

5. A semiconductor device, comprising:
a first layer formed in a semiconductor substrate and having a resistivity greater than 10 Ωcm and less than 1 kΩcm;
a second layer formed on a surface of the semiconductor substrate so as to be located above the first layer;
two semiconductor elements or two semiconductor circuits formed either in said second layer or on said second layer; and
at least one isolation region that either electrically isolates said two semiconductor elements or that electrically isolates said two semiconductor circuits, said
at least one isolation region being located either between said two semiconductor elements or between said two semiconductor circuits and formed in the semiconductor substrate so as to reach said first layer from the surface of the semiconductor substrate, said at least one isolation region comprising two isolation regions formed either between said two semiconductor elements or between said two semiconductor circuits,
wherein a first isolation region of said two isolation regions surrounds one of said two semiconductor elements or one of said two semiconductor circuits, and
wherein a second isolation region of said two isolation regions surrounds said first isolation region.

6. A semiconductor device, comprising:
a first layer which is formed in a semiconductor substrate and has a first layer formed in a semiconductor substrate and having a resistivity greater than 10 Ωcm and less than 1 kΩcm;
a second layer formed on a surface of the semiconductor substrate so as to be located above the first layer;
two semiconductor elements or two semiconductor circuits formed either in said second layer or on said second layer; and
at least one isolation region that either electrically isolates said two semiconductor elements or that electrically isolates said two semiconductor circuits, said
at least one isolation region being located either between said two semiconductor elements or between said two semiconductor circuits and formed in the semiconductor substrate so as to reach said first layer from the surface of the semiconductor substrate, said at least one isolation region comprising two isolation regions formed either between said two semiconductor elements or between said two semiconductor circuits; and
a low resistivity region formed between said two isolation regions in said second layer having a fixed potential value and having a resistivity lower than the resistivity of said second layer.

7. A semiconductor device, comprising:
a first layer which is formed in a semiconductor substrate and has a first layer formed in a semiconductor substrate and having a resistivity greater than 10 Ωcm and less than 1 kΩcm;
a second layer formed on a surface of the semiconductor substrate so as to be located above the first layer;
two semiconductor elements or two semiconductor circuits formed either in said second layer or on said second layer; and
at least one isolation region that either electrically isolates said two semiconductor elements or that electrically isolates said two semiconductor circuits, said at least one isolation region being located either between said two semiconductor elements or between said two semiconductor circuits and formed in the semiconductor substrate so as to reach said first layer from the surface of the semiconductor substrate; and
an embedded layer having a conductivity type which is different from a conductivity type of said first layer and formed in said first layer so as to contact said second layer.

8. A semiconductor device, comprising:
a first layer which is formed in a semiconductor substrate and has a first layer formed in a semiconductor substrate and having a resistivity greater than 10 Ωcm and less than 1 kΩcm;
a second layer formed on a surface of the semiconductor substrate so as to be located above the first layer;
two semiconductor elements or two semiconductor circuits formed either in said second layer or on said second layer; and
at least one isolation region that either electrically isolates said two semiconductor elements or that electrically isolates said two semiconductor circuits, said at least one isolation region being located either between said two semiconductor elements or between said two semiconductor circuits and formed in the semiconductor substrate so as to reach said first layer from the surface of the semiconductor substrate; and
an embedded layer which is formed in said first layer so as to contact said second layer and has a resistivity lower than the resistivity of said first layer.
